(19) United States
(12) Patent Application Publication
(10) Pub. No.: US 2014/0190413 A1
(43) Pub. Date: Jul. 10, 2014

(54) APPARATUS FOR FABRICATING INGOT

(71) Applicants: Chang Hyun Son, Seoul (KR); Dong Geun Shin, Seoul (KR)

(72) Inventors: Chang Hyun Son, Seoul (KR); Dong Geun Shin, Seoul (KR)

(73) Assignee: LG INNOTEK CO., LTD., Seoul (KR)

(21) Appl. No.: 14/126,737

(22) PCT Filed: Jun. 14, 2012
(86) PCT No.: PCT/KR2012/004702

§ 371 Date: Mar. 21, 2014

(30) Foreign Application Priority Data
Jun. 14, 2011 (KR) 10-2011-0057429

(51) Int. Cl. C30B 23/00

(52) U.S. Cl. CPC C30B 23/002
USPC 118/726

(57) ABSTRACT

Disclosed is an apparatus for fabricating an ingot. The apparatus comprises a crucible to receive a source material, and a temperature difference compensating part on the source material. The temperature difference compensating part comprises a plurality of holes.

### TECHNICAL FIELD

The disclosure relates to an apparatus for fabricating an ingot.

### BACKGROUND ART

SiC represents the superior thermal stability and superior oxidation-resistance property. In addition, the SiC has the superior thermal conductivity of about 4.6 W/Cm?, so the SiC can be used for fabricating a large-size substrate having a diameter of about 2 inches or above. In particular, the single crystal growth technology for the SiC is very stable actually, so the SiC has been extensively used in the industrial field as a material for a substrate.

In the case of SiC, a scheme of growing the single crystal for SiC using a seed has been suggested. In this case, after putting SiC powders serving as a source material in a crucible, a SiC single crystal is provided on the source material. Temperature gradient is formed between the source material and the seed, so that the source material in the crucible is dispersed to the seed, and re-crystallized to grow a single crystal.

When growing the single crystal, a temperature gradient is formed in a horizontal region of the source material. The temperature gradient is varied depending on the distance from a crucible. Therefore, a sublimation amount of the source material varies. The single crystal has a convex shape due to the temperature gradient, and defects may occur in the single crystal.

### DISCLOSURE OF INVENTION

### Technical Problem

The embodiment can grow a high-quality single crystal.

### Solution to Problem

According to the embodiment, there is provided an apparatus for fabricating an ingot. The apparatus comprises a crucible to receive a source material, and a temperature difference compensating part positioned on the source material. The temperature difference compensating part comprises a plurality of holes.

### Advantageous Effects of Invention

As described above, the apparatus of fabricating the ingot according to the embodiment comprises a temperature difference compensating part. The temperature difference compensating part comprises a plurality of holes and a plurality of partitions.

The temperature difference compensating part can comprise a plurality of holes having sizes different from each other. Accordingly, the source material provided at the central area can be smoothly sublimated, and the sublimation of the source material provided at the outer area can be restricted. Therefore, the growing of the single crystal can be minimized, and the high-quality single crystal can be grown. In addition, the sublimated silicon carbide gas can be prevented from being condensed, so that the feeding speed of the silicon carbide gas can be improved.

In addition, the holes and partitions of the temperature difference compensating part can make the temperature gradient uniform in the horizontal area of the source material. Therefore, the single crystal can be prevented from being grown in the convex shape due to the temperature gradient, so that the single crystal can be grown in a flat shape. Therefore, the yield rate of the wafer prepared by using the single crystal can be increased. In addition, as the convex degree of the single crystal is reduced, the probability for the defects of the single crystal is reduced. Therefore, a high-quality single crystal can be improved.

Since the source material can be maintained at the high temperature due to the temperature difference compensating part, an amount of the sublimated source material can increased, and the rate of growing the single crystal can be increased. The increase in the growing rate of the single crystal can be reduced, and the power consumption can be reduced. The effective use of the source material is increased.

### BRIEF DESCRIPTION OF DRAWINGS

FIG. 1 is a sectional view showing an apparatus for fabricating an ingot according to the embodiment;

FIG. 2 is a perspective view showing a temperature difference compensating part constituting the apparatus for fabricating the ingot according to the embodiment; and

FIGS. 3 to 8 are sectional views showing the manufacturing process of the apparatus for fabricating the ingot according to the embodiment.

### MODE FOR THE INVENTION

In the description of the embodiments, it will be understood that, when a layer (or film), a region, a pattern, or a structure is referred to as being “on” or “under” another layer (or film), another region, another pad, or another pattern, it can be “directly” or “indirectly” on the other layer (or film), region, pad, or pattern, or one or more intervening layers may also be present. Such a position of the layer has been described with reference to the drawings.

The thickness and size of each layer (film), region, pattern, or structure shown in the drawings may be exaggerated, omitted or schematically drawn for the purpose of convenience or clarity. In addition, the size of each layer (film), region, pattern, or structure does not utterly reflect an actual size.

Hereinafter, the embodiment of the disclosure will be described in detail with reference to accompanying drawings.

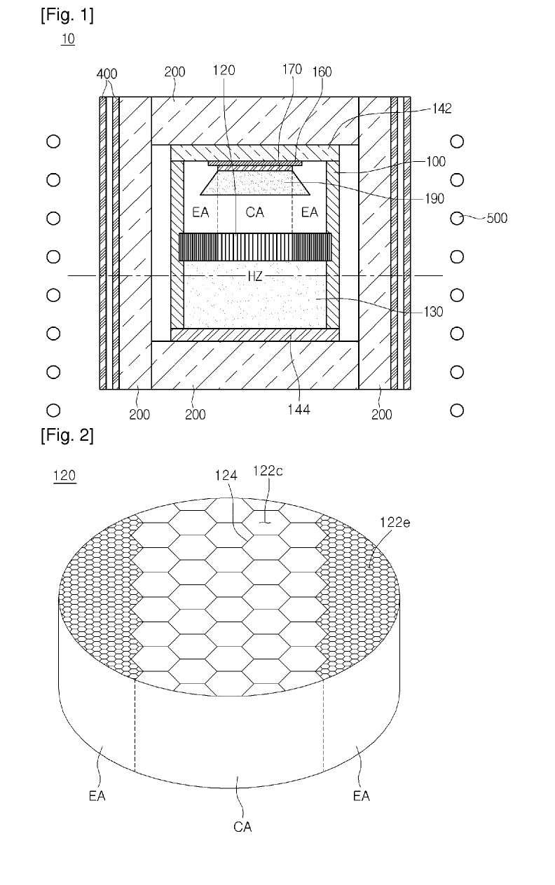

Hereinafter, an apparatus for fabricating an ingot according to the embodiment will be described in detail with reference to FIGS. 1 and 2. FIG. 1 is a sectional view showing the apparatus for fabricating an ingot according to the embodiment, and FIG. 2 is a perspective view showing a temperature difference compensating part constituting the apparatus for fabricating the ingot according to the embodiment.

Referring to FIGS. 1 and 2, an apparatus 10 for fabricating the ingot according to the embodiment comprises a crucible 100, a temperature difference compensating part 120, an upper cover 142, a lower cover 144, a seed holder 160, an adiabatic material 200, a quartz tube 400, and a heat induction part 500.

The crucible 100 receives source materials 130 therein.

The crucible 100 has a cylindrical shape to receive the source materials 130.

The crucible 100 may comprise a material having the melting point higher than the sublimation temperature of the SiC.

For example, the crucible 100 can be manufactured by using graphite.

In addition, the crucible 100 can be manufactured by coating a material having the melting point higher than the sublimation temperature of the SiC on the graphite. Preferably, a material, which is chemically inert with respect to silicon and hydrogen at the growth temperature for the SiC single crystals 192 and 194, is used as the material coated on the graphite. For example, the material may comprise metal carbide or nitride carbide. In particular, a mixture including at least two of Ta, Hf, Nb, Zr, W and V and carbide including carbon can be coated on the graphite. Further, a mixture including at least two of Ta, Hf, Nb, Zr, W and V and nitride including nitrogen can be coated on the graphite.

The source materials 130 may comprise silicon and carbon. In detail, the source materials 130 may comprise a compound including silicon, carbon, oxygen, and hydrogen. The source materials 130 may comprise SiC powders or polycarbosilane.

The temperature difference compensating part 120 may be provided in the crucible 100. In detail, the temperature difference compensating part 120 may be provided on the source materials 130. In addition, the temperature difference compensating part 120 may be provided on the entire surface of the source material 130.

The temperature difference compensating part 120 may comprise a plurality of holes 122c and 122e. The holes 122c and 122e may have the shape of a polygonal prim. Preferably, the holes 122c and 122e may have the shape of a hexagonal prism. The holes 122c and 122e may have the optimized temperature uniformity when the holes 122c and 122e have the shape of a hexagonal prism. However, since the embodiment is not limited thereto, the holes 122c and 122e may have the shape of a cylinder.

The temperature difference compensating part 120 may comprise a central area CA and an outer area EA surrounding the central area CA. In detail, the central area CA may correspond to the seed holder 160.

The size of the hole 122c provided in the central area CA may be greater than the size of the hole 122e provided in the outer area EA. Accordingly, the temperature difference between the central area CA and the outer area EA can be compensated, so that the uniform temperature can be maintained. Therefore, the source material 130 provided at the central area CA can be more smoothly sublimated, and the sublimation of the source material 130 provided at the outer area EA may be restricted. Therefore, the growth of a multi-crystal formed at the outer portion of the seed 170 can be minimized. Accordingly, the high-quality single crystal can be grown.

The sizes of the holes 122c and 122e may be in the range of 0.1 cm² to 10 cm². If the sizes of the holes 122c and 122e are less than of 0.1 cm², the sublimation of the source material 130 may be interrupted. Therefore, the growing speed of the single crystal may be degraded. In addition, if the sizes of the holes 122c and 122e exceed 10 cm², the durability of the temperature difference compensating part 120 may be degraded. However, the embodiment is not limited thereto. Accordingly, the sizes of the holes 122c and 122e may be varied according to the size, the structure, and the manufacturing conditions of the crucible 100.

The temperature difference compensating part 120 may comprise partitions 124 between the holes 122c and 122e. The partitions 124 may space the holes 122c and 122e away from each other. Each partition 124 may have a thickness of 1 mm to 1 cm. If the partition 124 is less than 1 mm, the durability of the temperature difference compensating part 120 may be degraded. If the partition 124 exceeds 1 cm, the sizes of the holes 122c and 122e are reduced, so that a predetermined influence may be exerted on the sublimation speed of the source material 130. However, the embodiment is not limited thereto, and the thickness of the partition 124 may be varied according to the size, the structure, and the manufacturing conditions of the crucible 100.

The temperature difference compensating part 120 may comprise at least one selected from the group consisting of graphite, silicon carbide, and tantalum. The materials emit heat by the heat induction part 500. However, the embodiment is not limited thereto, and the temperature difference compensating part 120 may comprise various materials to emit heat without the deformation thereof at the temperature of 2,000° C. or more.

The temperature difference compensating part 120 may have a thickness t in the range of 0.5 mm to 10 cm. If the temperature difference compensating part 120 has the thickness less than 0.5 mm, the temperature difference compensating part 120 may not make the temperature gradient uniform. If the temperature difference compensating part 120 has the thickness t exceeding 10 cm, the sublimation speed of the source material 130 may be degraded. However, the embodiment is not limited, and the thickness of the temperature difference compensating part 120 may be varied according to the size, the structure, and the manufacturing conditions of the crucible 100.

The temperature difference compensating part 120 may make the temperature gradient uniform in the horizontal area of the source material 130 to uniformly sublimate the source material 130 provided at the central area CA and the outer area EA. Accordingly, the consumption efficiency of the source material 130 can be increased, and the defects of the single crystal can be minimized. In addition, the sublimated silicon carbide gas can be prevented from being condensed, so that the feeding speed of the silicon carbide gas can be improved.

Conventionally, temperature gradient is formed in a horizontal area of a source material. The temperature gradient may be varied according to the distances from the crucible 100. In other words, the crucible 100 emits heat by the heat induction part 500, and the source material 130 closer to the crucible 100, that is, the source material 130 provided at the outer area EA represents a high temperature. However, the source material 130 farther away from the crucible 100, that is, the source material 130 provided at the central area CA represents a low temperature.

Accordingly, the difference in the sublimation degree on the surface of the source material 130 is made. The surface of the source material 130 provided at the outer region EA is significantly sublimated, but the surface of the source material 130 provided at the central area CA is less sublimated. This temperature gradient is increased as time elapses. This is because the temperature of the outer region EA is more increased due to graphitization of the source material 130 provided at the outer region EA as the sublimation of the source material 130 provided at the outer region EA is increased.

The single crystal may be grown in the convex shape due to the difference in the sublimation degree and the temperature gradient, and the yield rate of the wafer prepared by using the single crystal may be reduced.

Thereafter, the upper cover 142 may be positioned at the upper portion 102 of the crucible 100. The upper cover 142 may seal the crucible 100. The upper cover 142 may comprise graphite.

In addition, the lower cover 144 may be positioned at the lower portion 104 of the crucible 100. The lower cover 144 may seal the crucible 100. The lower cover 142 may comprise graphite.

The seed holder 160 is positioned at the lower end portion of the upper cover 142.

The seed holder 160 may fix the seed 170. The seed holder 160 may comprise high-concentration graphite.

The seed 170 is attached to the seed holder 160. The seed 170 is attached to the seed holder 160 so that the single crystal 190 can be prevented from being grown to the upper cover 142. However, the embodiment is not limited thereto, and the seed 170 may be directly attached to the upper cover 142.

Thereafter, the adiabatic material 200 surrounds the crucible 100. The adiabatic material 200 keeps the temperature of the crucible 100 to the level of the crystal growth temperature. Since the crystal growth temperature of the SiC is high, graphite felt may be used as the adiabatic material 200. In detail, the adiabatic material 200 may comprise a cylindrical graphite felt having a predetermined thickness prepared by compressing graphite fiber. In addition, the adiabatic material 200 may be prepared as a plurality of layers to surround the crucible 100.

The quartz tube 400 is positioned at an outer peripheral surface of the crucible 100. The quartz tube 400 is fitted around the outer peripheral surface of the crucible 100. The quartz tube 400 may block heat transferred into a single crystal growth apparatus from the heat induction part 500. The quartz tube 400 is a hollow tube and cooling water may circulate through an inner space of the quartz tube 400.

The heat induction part 500 is positioned outside the crucible 100. For instance, the heat induction part 500 is an RF induction coil. As RF current is applied to the RF induction coil, the crucible 100 and the source material 130 can be heated. That is, the source materials 130 contained in the crucible 100 can be heated to the desired temperature.

The central area of the heat induction part 500 is located below the center area of the crucible 100. Thus, the temperature gradient may occur at the upper and lower portions of the crucible 100 so that areas heated at different temperatures appear at the upper and lower portions of the crucible 100. That is, the central area (hot zone; HZ) of the heat induction part 500 is located relatively lower than the central area of the crucible 100, so the temperature of the lower portion of the crucible 100 may be higher than the temperature of the upper portion of the crucible 100 on the basis of the hot zone HZ. In addition, the temperature may rise from the center of the crucible 100 to the outer peripheral portion of the crucible 100. Due to the temperature gradient, the SiC source materials may be sublimated so that the sublimated SiC gas moves to the surface of the seed 170 having the relatively low temperature. Thus, the SiC gas is re-crystallized, so the SiC single crystal is grown.

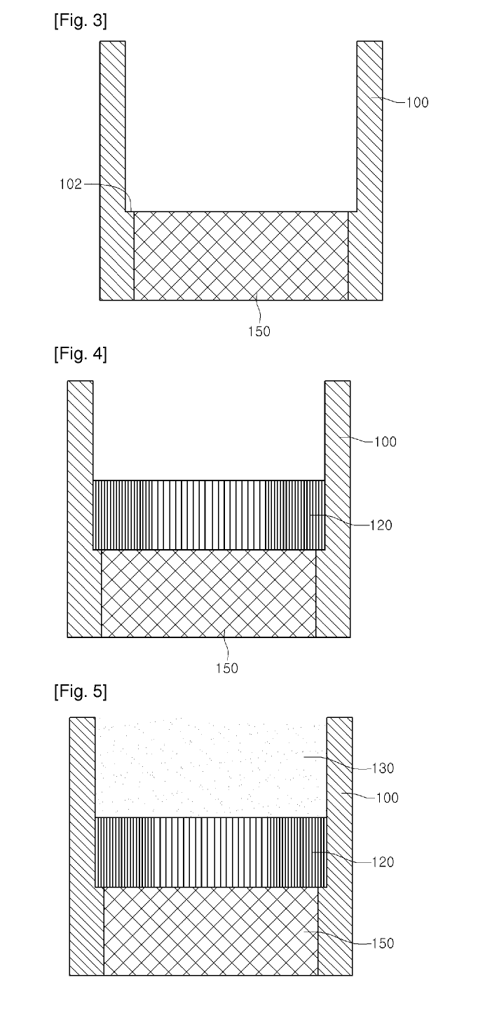

Hereinafter, a method of fabricating the ingot will be described with reference to FIGS. 3 to 8.

FIGS. 3 to 8 are sectional views showing the processes of fabricating the ingot according to the embodiment.

Referring to FIG. 3, the crucible 100, which is upside down, is prepared. A plate 150 is provided in the upside down crucible 100. The plate 150 may support the temperature difference compensating part 120 and the source material 130 placed on the plate 150 and may fix the positions of the temperature difference compensating part 120 and the source material 130. The plate 150 may comprise a carbon material. The plate 150 may not comprise heterogeneous impurities, for example, materials such as metallic elements or high boiling point elements, so that the plate 150 is prevented from contaminating the crucible 100 and the source material 130.

Thereafter, referring to FIG. 4, the temperature difference compensating part 120 having holes may be provided on the plate 150. The crucible 100 comprises a locking part 102 so that the temperature difference compensating part 120 may be locked with the locking part 102.

Then, referring to FIG. 5, the source material 130 may be placed on the temperature difference compensating part 120.

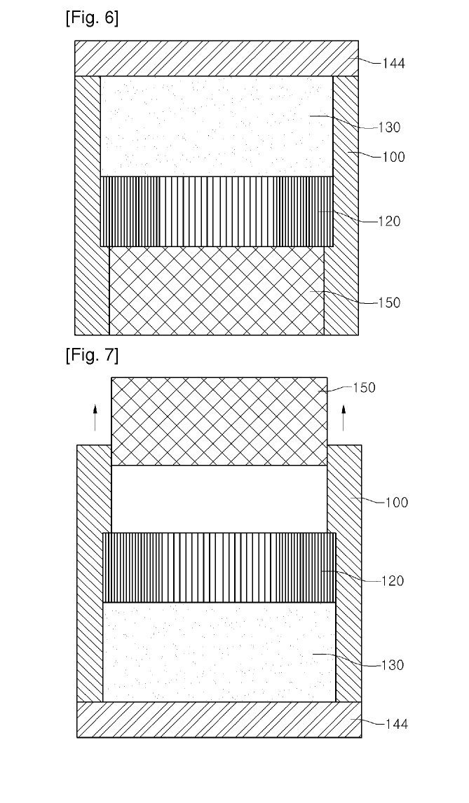

Subsequently, referring to FIG. 6, the lower cover 144 is covered on the crucible 100 to close the crucible 100.

Thereafter, referring to FIG. 7, after overturning the crucible 100 shown in FIG. 6, the plate 150 may be removed from the crucible 100.

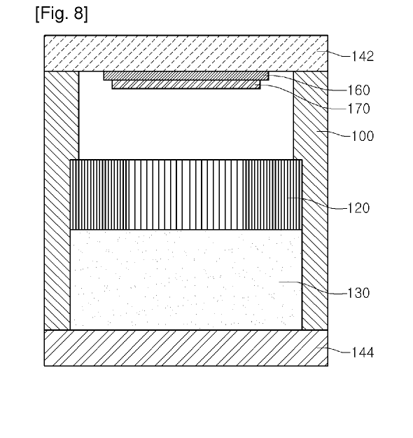

Then, referring to FIG. 8, the upper cover 142 including the seed holder 160 having the seed 170 attached thereto may be placed on the upper portion of the crucible 100. Accordingly, the crucible 100 can be firmly sealed and can grow a single crystal.

Any reference in this specification to “one embodiment,” “an embodiment,” “example embodiment,” etc., means that a particular feature, structure, or characteristic described in connection with the embodiment is comprised in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. An apparatus for fabricating an ingot, the apparatus comprising:
a crucible to receive a source material; and
a temperature difference compensating part on the source material, wherein the temperature difference compensating part comprises a plurality of holes.

2. The apparatus of claim 1, wherein the temperature difference compensating part comprises a central area and an outer area surrounding the central area, and a size of each hole at the central area is greater than a size of each hole at the outer region.

3. The apparatus of claim 2, further comprising a seed holder at an upper portion of the crucible, wherein the central area corresponds to the seed holder.

4. The apparatus of claim 1, wherein each hole has a shape of a polygonal prism.

5. The apparatus of claim 1, wherein each hole has a shape of a hexagonal prism.

6. The apparatus of claim 1, wherein each hole has a shape of a cylinder.

7. The apparatus of claim 1, further comprising a partition between the holes.

8. The apparatus of claim 1, wherein the temperature difference compensating part is placed on an entire surface of the source material.

9. The apparatus of claim 1, wherein the temperature difference compensating part has a thickness of 0.5 mm to 10 cm.

10. The apparatus of claim 1, wherein a size of each hole is in a range of 0.1 cm² to 10 cm².

11. The apparatus of claim 7, wherein the partition has a thickness in a range of 1 mm to 1 cm.

12. The apparatus of claim 1, wherein the temperature difference compensating part comprises at least one selected from the group consisting of graphite, silicon carbide, and tantalum.

13. The apparatus of claim 12, wherein the temperature difference compensating part emits heat.

14. The apparatus of claim 1, wherein the temperature difference compensating part is placed on an entire surface of the source material.

15. The apparatus of claim 1, wherein the crucible is provided at an upper portion thereof with an upper cover, and provided at a lower portion thereof with a lower cover.

16. The apparatus of claim 1, further comprising a locking part to support the temperature difference compensating part in the crucible.

17. The apparatus of claim 1, wherein the locking part protrudes in the crucible.
